(19) United States
(12) Patent Application Publication
(10) Pub. No.: US 2026/0214985 A1
(43) Pub. Date: Jul. 23, 2026

(54) SEMICONDUCTOR DEVICE USING NITROGEN-DOPED SILICON OXIDE AND ITS MANUFACTURING METHOD

(71) Applicant: IUCF-HYU (INDUSTRY-UNIVERSITY COOPERATION FOUNDATION HANYANG UNIVERSITY), Seoul (KR)

(72) Inventors: Jin Seong PARK, Seongnam-si (KR); Tae Heon KIM, Goyang-si (KR); Dong Gyu KIM, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 19/451,095

(22) Filed: Jan. 16, 2026

(30) Foreign Application Priority Data
Jan. 21, 2025 (KR) 10-2025-0008673

(51) Int. Cl. H10D 86/01; H10D 86/40

(52) U.S. Cl. CPC H10D 86/0221; H10D 86/423; H10D 86/425; H10D 86/471

(57) ABSTRACT

Provided is a method for manufacturing a semiconductor device. The method for manufacturing the semiconductor device comprises: forming a source electrode and a drain electrode on a substrate to be spaced apart from each other; forming an active layer on the substrate exposed between the source electrode and the drain electrode such that one side is in contact with the source electrode and the other side is in contact with the drain electrode; forming a gate insulating layer on the substrate to cover the source electrode, the drain electrode, and the active layer; and forming a gate electrode on the gate insulating layer, in which the gate insulating layer is formed by plasma enhanced atomic layer deposition (PEALD) using a precursor including silicon (Si) and a reactant including nitrogen (N) and oxygen (O).

### BACKGROUND OF THE INVENTION

### 1. Field of the Invention

The present invention relates to a semiconductor device using a nitrogen-doped silicon oxide and a method for manufacturing the same.

### 2. Description of the Prior Art

In—Ga—Zn—O (IGZO) has attracted attention in the display industry since Hosono and others first proved its potential in 2004. IGZO provides a high field effect mobility (μ_{FE}) of 10-30 cm²/V·s and a low leakage current of 10⁻¹⁸ A/μm or less while having an amorphous structure, and thus has become a material capable of replacing an existing amorphous silicon (a-Si). In addition, IGZO maintains excellent electrical uniformity even at a low manufacturing temperature of 400° C. or less, and provides a consistent performance even over a large area. This property makes the IGZO an ideal material for applying an active matrix organic light emitting diode (AMOLED) of devices such as smart phones, tablets, notebooks, and high-end TVs requiring high resolution and low power operation.

In the future, it will become important to secure the stability of a highly integrated oxide thin film transistor (TFT) in the display industry, particularly in the AR/VR application field. To solve this problem, a vertical TFT, a channel omnidirectional structure (CAA), a gate omnidirectional structure (GAA), and the like have been proposed, and atomic layer deposition (ALD) plays an important role in their implementation. The ALD process provides a low deposition temperature, high aspect ratio compatibility, precise thickness control, and in particular, plasma enhanced ALD (PEALD) may be more advantageous than thermal-ALD (T-ALD) in display applications where processing at low temperatures and high productivity are required. However, even PEALD-based oxide TFTs suffer from issues related to reliability and sensitivity to hydrogen (H) exposure. Reliability issues are mainly affected by active layer/gate insulator (GI) interface properties, and thermodynamic instability may lead to defect formation. This affects device performance as charges (e⁻, h⁺) are trapped under a positive bias temperature stress (PBTS) and a negative bias temperature stress (NBTS).

Meanwhile, a SiN_{X} or SiON film manufactured through plasma enhanced chemical vapor deposition (PECVD) is frequently used as an encapsulation layer for protecting an organic layer in an OLED. When NH₃ is used as a reactant in the encapsulation layer, a considerable amount of hydrogen (H) may be generated and diffused to below IGZO TFT. In IGZO TFT, hydrogen (H) may exist in the form of interstitial hydrogen (Hi⁺, Hi) and substitution hydrogen (HO, HO). Hi and HO contribute to electron generation, and Hi and HO induce electron trapping. Since these positive and negative charges coexist, hydrogen (H) may exhibit dual stability, which may lead to device degradation and changes in electrical performance. Thus, it is essential to develop a strategy capable of precisely controlling an interface of the oxide TFT and maintaining stable electrical properties even when exposed to hydrogen (H).

SiO₂ is widely used as a gate insulator of IGZO TFT due to its excellent insulating properties and thermal stability. When SiO₂ is applied as a gate insulator, a channel is formed at an interface between an active layer and the gate insulator, and thus various factors need to be considered. In the PEALD process, factors affecting the interface properties of the SiO₂ include a deposition temperature, a type of reactant, a plasma duration, and power, and in particular, plasma power has an important influence. However, SiO₂ has a lower density and hardness than SiON and SiN_{X}, and thus has a limited ability to block the diffusion of external hydrogen (H). Accordingly, the present invention is intended to provide a technology capable of effectively blocking the diffusion of external hydrogen (H) while using SiO₂ as a gate insulator.

### SUMMARY OF THE INVENTION

One technical object of the present invention may provide a semiconductor device using a nitrogen-doped silicon oxide and a method for manufacturing the same.

Another technical object of the present invention may provide a semiconductor device capable of effectively blocking diffusion of hydrogen into an active layer and a method for manufacturing the same.

Still another technical object of the present invention may provide a semiconductor device with high reliability and a method for manufacturing the same.

The technical problems to be solved by the present invention is not limited to the above-described problems.

In order to solve the above-described technical problems, the present invention may provide a method for manufacturing a semiconductor device.

According to one embodiment, the method for manufacturing the semiconductor device may include: forming a source electrode and a drain electrode on a substrate to be spaced apart from each other; forming an active layer on the substrate exposed between the source electrode and the drain electrode such that one side is in contact with the source electrode and the other side is in contact with the drain electrode; forming a gate insulating layer on the substrate to cover the source electrode, the drain electrode, and the active layer; and forming a gate electrode on the gate insulating layer, in which the gate insulating layer is formed by plasma enhanced atomic layer deposition (PEALD) using a precursor including silicon (Si) and a reactant including nitrogen (N) and oxygen (O).

According to one embodiment, the reactant may include nitrous oxide (N₂O) plasma, in which a plasma power of the reactant is controlled to be more than 100 W and less than 200 W.

According to one embodiment, the gate insulating layer may prevent hydrogen from permeating into the active layer.

According to one embodiment, as the gate insulating layer is formed by the plasma enhanced atomic layer deposition (PECVD), a dangling bond may be formed in the gate insulating layer, and as the dangling bond in the gate insulating layer is bonded to hydrogen, the permeation of hydrogen into the active layer may be prevented.

According to one embodiment, the gate insulating layer may include a nitrogen-doped silicon oxide (SiO₂).

According to one embodiment, the forming of the gate insulating layer may include: providing the precursor on the substrate; a primary purge step of removing unreacted impurities on the substrate provided with the precursor; providing the reactant on the substrate; and a secondary purge step of removing the unreacted impurities on the substrate provided with the reactant.

According to one embodiment, the method for manufacturing the semiconductor device may further include heat-treating the active layer after the forming of the gate electrode.

According to another embodiment, the method for manufacturing the semiconductor device may include: forming a source electrode and a drain electrode on a substrate to be spaced apart from each other; forming an active layer on the substrate exposed between the source electrode and the drain electrode such that one side is in contact with the source electrode and the other side is in contact with the drain electrode; forming a first gate insulating layer on the substrate to cover the source electrode, the drain electrode, and the active layer; forming a second gate insulating layer on the first gate insulating layer; and forming a gate electrode on the second gate insulating layer, in which the first gate insulating layer and the second gate insulating layer are all formed by plasma enhanced atomic layer deposition (PEALD) using a precursor including silicon (Si) and a reactant including nitrogen (N) and oxygen (O).

According to another embodiment, the reactant may include nitrous oxide (N₂O) plasma, in which the reactant used in a process of forming the first gate insulating layer is controlled to have a relatively low plasma power, and the reactant used in a process of forming the second gate insulating layer is controlled to have a relatively high plasma power.

According to another embodiment, the reactant used in the process of forming the first gate insulating layer may be controlled to have a plasma power of 150 W, and the reactant used in the process of forming the second gate insulating layer may be controlled to have a plasma power of 300 W.

In order to solve the above-described technical problems, the present invention may provide a semiconductor device.

According to one embodiment, the semiconductor device may include: a source electrode disposed on a substrate; a drain electrode disposed on the substrate to be spaced apart from the source electrode; an active layer disposed on the substrate exposed between the source electrode and the drain electrode such that one side is in contact with the source electrode and the other side is in contact with the drain electrode; a first gate insulating layer covering the source electrode, the drain electrode, and the active layer and including a nitrogen-doped silicon oxide; a second gate insulating layer disposed on the first gate insulating layer and including a nitrogen-doped silicon oxide; and a gate electrode disposed on the second gate insulating layer, in which a content of nitrogen in the second gate insulating layer is greater than a content of nitrogen in the first gate insulating layer.

According to one embodiment, the content of nitrogen in the first gate insulating layer may be less than 1 at %, and the content of nitrogen in the second gate insulating layer may be greater than 2 at %.

According to one embodiment, a hydrogen permeability of the second gate insulating layer may be lower than a hydrogen permeability of the first gate insulating layer.

According to one embodiment, the active layer may include an indium gallium zinc oxide (IGZO).

According to an embodiment of the present invention, a method for manufacturing a semiconductor device may include: forming a source electrode and a drain electrode on a substrate to be spaced apart from each other; forming an active layer on the substrate exposed between the source electrode and the drain electrode such that one side is in contact with the source electrode and the other side is in contact with the drain electrode; forming a gate insulating layer on the substrate to cover the source electrode, the drain electrode, and the active layer; and forming a gate electrode on the gate insulating layer, in which the gate insulating layer is formed by plasma enhanced atomic layer deposition (PEALD) using a precursor including silicon (Si) and a reactant including nitrogen (N) and oxygen (O). Accordingly, the diffusion of hydrogen into the active layer may be effectively blocked, and the semiconductor device having high reliability and high stability may be provided.

### BRIEF DESCRIPTION OF THE DRAWINGS

FIG. 1 is a flowchart for describing a method for manufacturing a semiconductor device according to a first embodiment of the present invention.

FIG. 2 is a schematic view for describing S110 in a method for manufacturing a semiconductor device according to a first embodiment of the present invention.

FIG. 3 is a schematic view for describing S120 in a method for manufacturing a semiconductor device according to a first embodiment of the present invention.

FIG. 4 is a view for specifically describing a process order of S120 in a method for manufacturing a semiconductor device according to a first embodiment of the present invention.

FIG. 5 is a schematic view for describing S130 in a method for manufacturing a semiconductor device according to a first embodiment of the present invention.

FIG. 6 is a view for specifically describing a process order of S130 in a method for manufacturing a semiconductor device according to a first embodiment of the present invention.

FIG. 7 is a schematic view for describing S135 in a method for manufacturing a semiconductor device according to a first embodiment of the present invention.

FIG. 8 is a schematic view for describing S140 in a method for manufacturing a semiconductor device according to a first embodiment of the present invention.

FIG. 9 is a flowchart for describing a method for manufacturing a semiconductor device according to a second embodiment of the present invention.

FIG. 10 is a schematic view for describing S210 in a method for manufacturing a semiconductor device according to a second embodiment of the present invention.

FIG. 11 is a schematic view for describing S220 in a method for manufacturing a semiconductor device according to a second embodiment of the present invention.

FIG. 12 is a schematic view for describing S230 in a method for manufacturing a semiconductor device according to a second embodiment of the present invention.

FIG. 13 is a schematic view for describing S240 in a method for manufacturing a semiconductor device according to a second embodiment of the present invention.

FIG. 14 is a schematic view for describing S245 in a method for manufacturing a semiconductor device according to a second embodiment of the present invention.

FIG. 15 is a schematic view for describing S250 in a method for manufacturing a semiconductor device according to a second embodiment of the present invention.

FIG. 16 is a view for describing various semiconductor devices to which a gate insulating layer according to embodiments of the present invention may be applied.

FIG. 17 is a view for describing the results of XPS N is analysis of material layers according to Experimental Examples 1-1 to 1-5 of the present invention.

FIG. 18 is a view for describing the results of XPS Si 2p analysis of material layers according to Experimental Examples 1-1 to 1-5 of the present invention.

FIG. 19 is a view for describing the results of Tof-SIMS SiN ions analysis of material layers according to Experimental Examples 1-1 to 1-5 of the present invention.

FIG. 20 is a view for describing the results of surface roughness analysis of material layers according to Experimental Examples 1-1 to 1-5 of the present invention.

FIG. 21 is a view for describing the results of measuring transfer properties of semiconductor devices according to Experimental Examples 2-1 to 2-5 of the present invention.

FIG. 22 is a view for describing the results of measuring threshold voltage and mobility of semiconductor devices according to Experimental Examples 2-1 to 2-5 of the present invention.

FIG. 23 is a view for describing the results of measuring subthreshold swing and hysteresis of semiconductor devices according to Experimental Examples 2-1 to 2-5 of the present invention.

FIG. 24 is a view for describing the calculated Nₘₐₓ and N_{ind} values of semiconductor devices according to Experimental Examples 2-1 to 2-5 of the present invention.

FIG. 25 is a view for describing the results of PBTS test of semiconductor devices according to Experimental Examples 2-1 to 2-5 of the present invention.

FIGS. 26 and 27 are views for describing the results of XPS analysis of active layers of semiconductor devices according to Experimental Examples 2-1 to 2-5 of the present invention.

FIG. 28 is a view for describing the results of hydrogen content analysis in the bulk of a gate insulating layer of semiconductor devices according to Experimental Examples 2-1 to 2-5 of the present invention.

FIG. 29 is a view for describing a change in properties shown after PBTS test of semiconductor devices according to Experimental Examples 2-1 to 2-5 of the present invention.

FIG. 30 is a view for describing the results of measuring transfer properties of semiconductor devices according to Experimental Examples 3-1 to 3-5 of the present invention.

FIG. 31 is a view for describing the results of measuring a hydrogen permeability of material layers according to Experimental Examples 3-1 to 3-5 of the present invention.

FIGS. 32 and 33 are views for describing the results of Tof-SIMS analysis of material layers according to Experimental Examples 3-1 to 3-5 of the present invention.

FIG. 34 is a view for describing the results of measuring transfer properties of semiconductor devices according to Experimental Examples 4-1 and 4-2 of the present invention.

FIGS. 35 and 36 are views for describing the results of PBTS test of semiconductor devices according to Experimental Examples 4-1 and 4-2 of the present invention.

FIG. 37 is a view for describing the results of measuring transfer properties of semiconductor devices according to Experimental Examples 5-1 to 5-3 of the present invention.

FIGS. 38 and 39 are views for describing the results of PBTS test of semiconductor devices according to Experimental Examples 5-1 to 5-3 of the present invention.

### DETAILED DESCRIPTION OF THE EXEMPLARY EMBODIMENTS

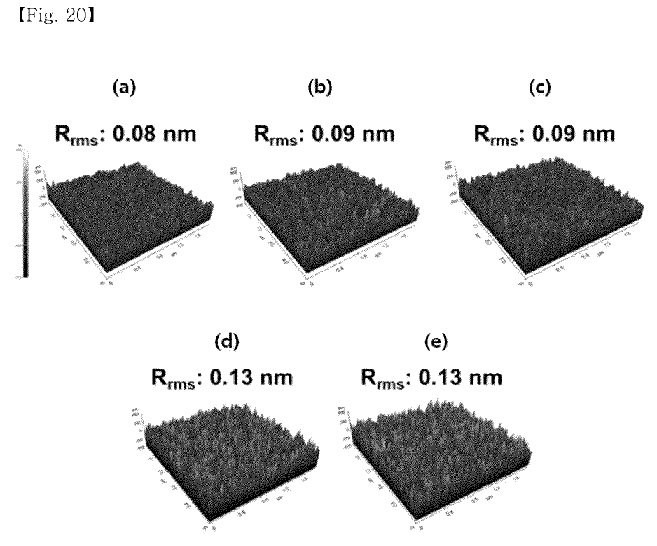

Referring to (a) to (e) of FIG. 20, they may show a root mean square surface roughness (Rrms) for a region of 2×2 μm² with respect to each of the material layers according to above Experimental Examples 1-1 to 1-5. More specifically, (a) of FIG. 20 may show a surface roughness of a material layer according to Experimental Example 1-1, (b) of FIG. 20 may show a surface roughness of a material layer according to Experimental Example 1-2, (c) of FIG. 20 may show a surface roughness of a material layer according to Experimental Example 1-3, (d) of FIG. 20 may show a surface roughness of a material layer according to Experimental Example 1-4, and (e) of FIG. 20 may show a surface roughness of a material layer according to Experimental Example 1-5.

As can be seen in (a) to (e) of FIG. 20, it can be confirmed that the material layer formed with a plasma power of 100 W to 200 W (Ex. 1-1 to Ex. 1-3) has a low surface roughness of less than 0.1 nm, whereas the material layer formed with a power of more than 200 W (Ex. 1-4, Ex. 1-5) has a high surface roughness of more than 0.1 nm. In other words, it can be confirmed that the surface roughness increases as the plasma power increases.

### Experimental Example 2: Comparison of Properties of TFT Device According to Plasma Power

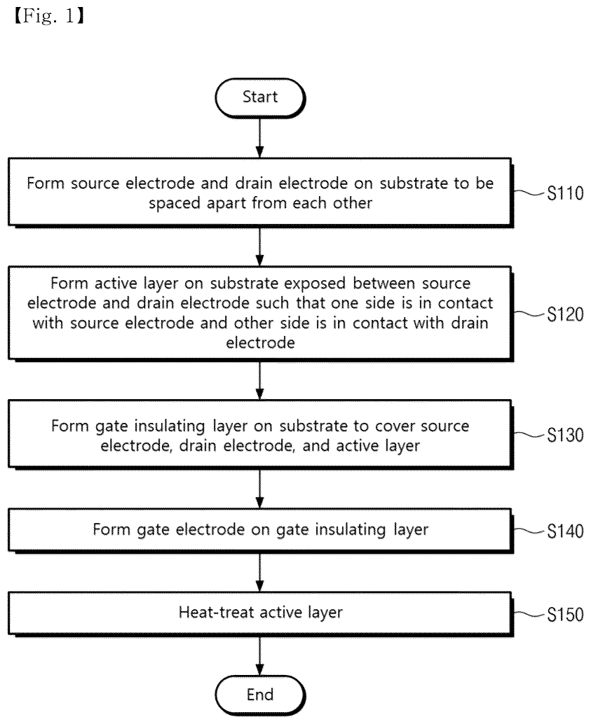

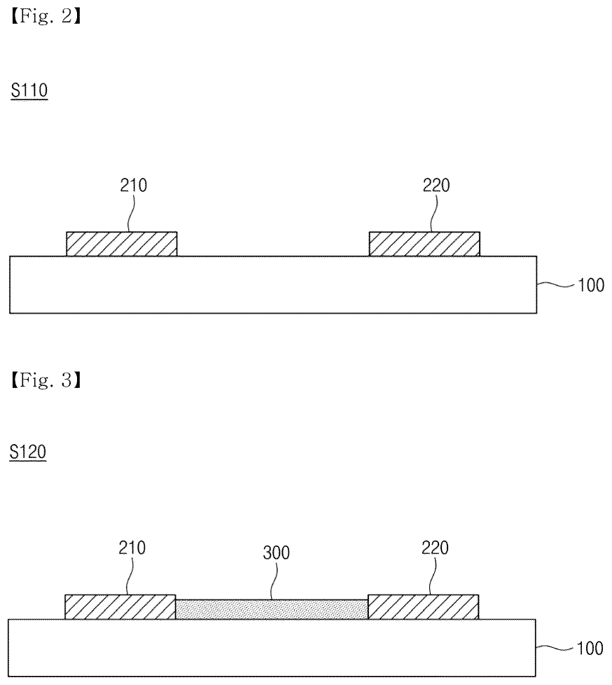

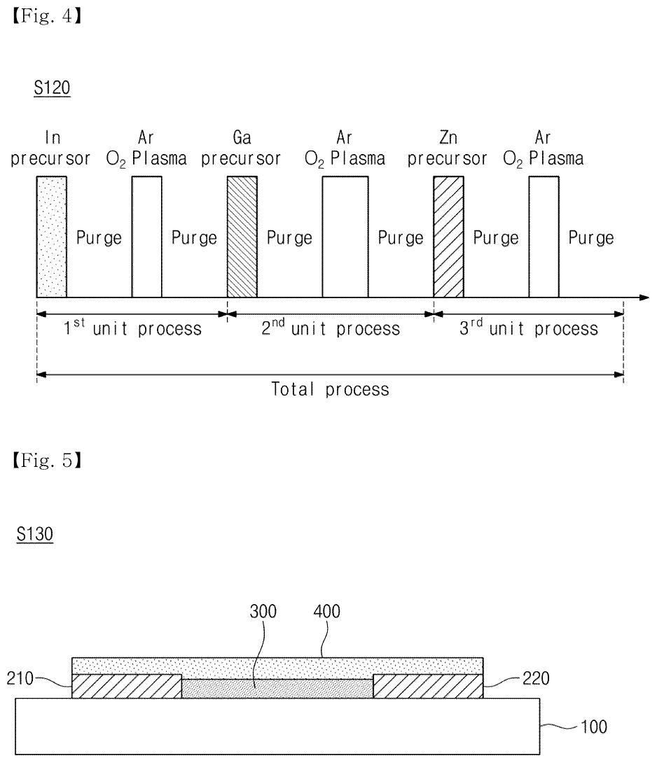

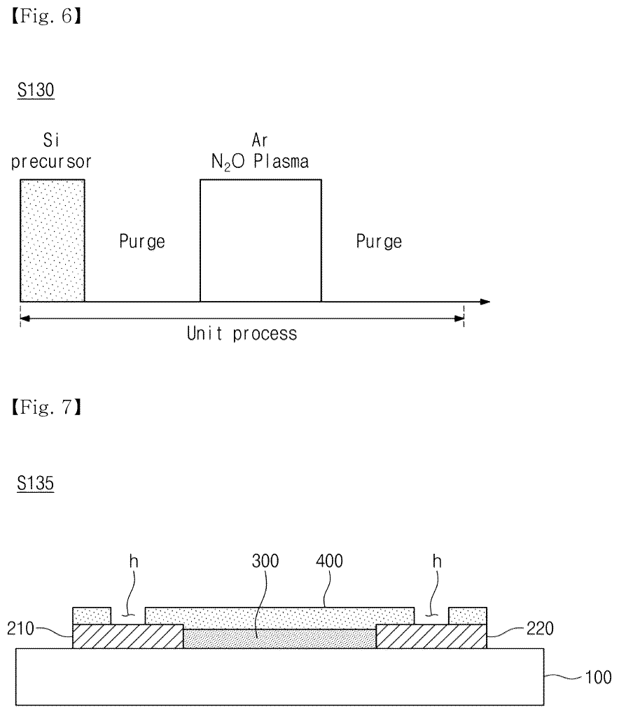

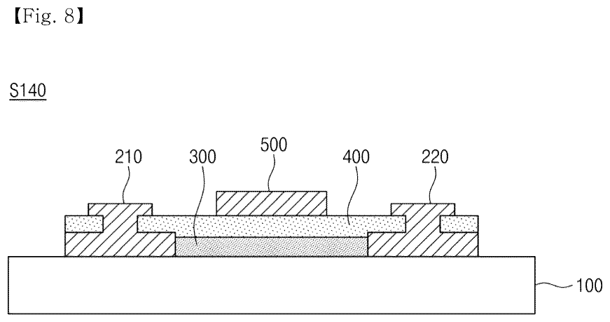

A TFT device having the structure as shown in FIG. 8 was manufactured by the method described with reference to FIGS. 1 to 8. More specifically, the source electrode and the drain electrode formed an ITO having a thickness of 100 nm by RF sputtering, the active layer formed an IGZO having a thickness of 20 nm by plasma enhanced atomic layer deposition using (3-dimethylaminopropyl)dimethylindium (DADI), trimethyl gallium (TMGa), diethyl zinc (DEZ), and N₂O plasma, the gate insulating layer formed a nitrogen-doped SiO₂ material layer with varying plasma power by the method described in Experimental Example 1, and the gate electrode formed an ITO having a thickness of 100 nm. In addition, heat treatment was finally performed at a temperature of 350° C. in a dry air environment for three hours to manufacture a TFT device.

The TFT device to which the material layer according to Experimental Example 1-1 is applied may be defined as a semiconductor device (Ex 2-1) according to Experimental Example 2-1, the TFT device to which the material layer according to Experimental Example 1-2 is applied may be defined as a semiconductor device (Ex 2-2) according to Experimental Example 2-2, the TFT device to which the material layer according to Experimental Example 1-3 is applied may be defined as a semiconductor device (Ex 2-3) according to Experimental Example 2-3, the TFT device to which the material layer according to Experimental Example 1-4 is applied may be defined as a semiconductor device (Ex 2-4) according to Experimental Example 2-4, and the TFT device to which the material layer according to Experimental Example 1-5 is applied may be defined as a semiconductor device (Ex 2-5) according to Experimental Example 2-5.

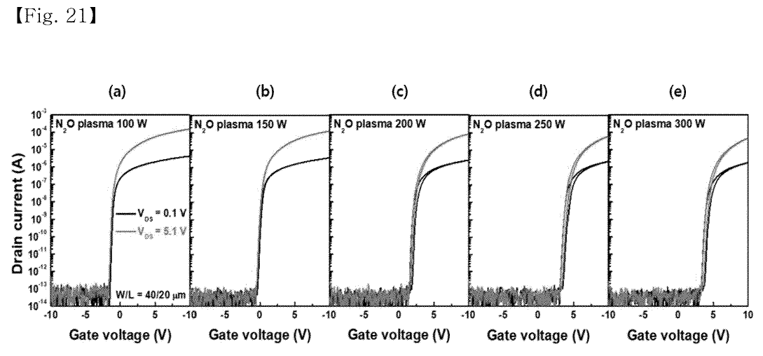

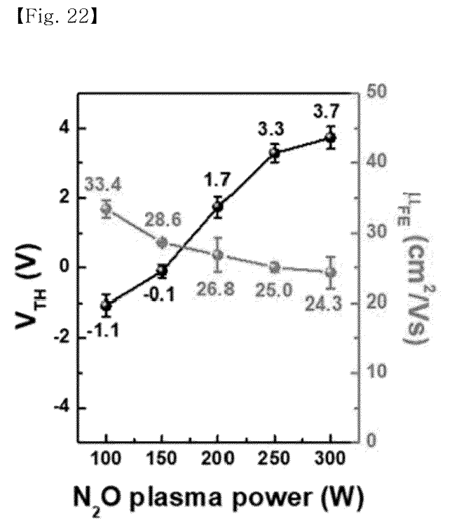

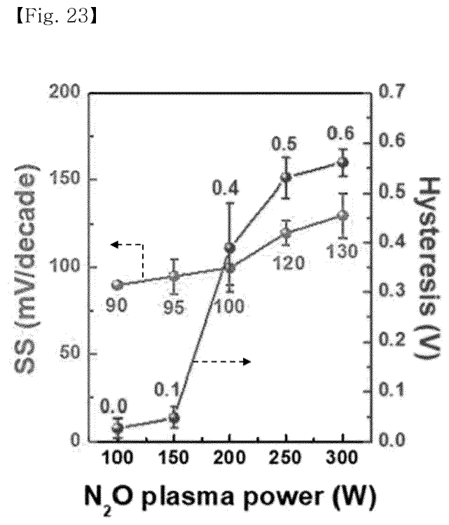

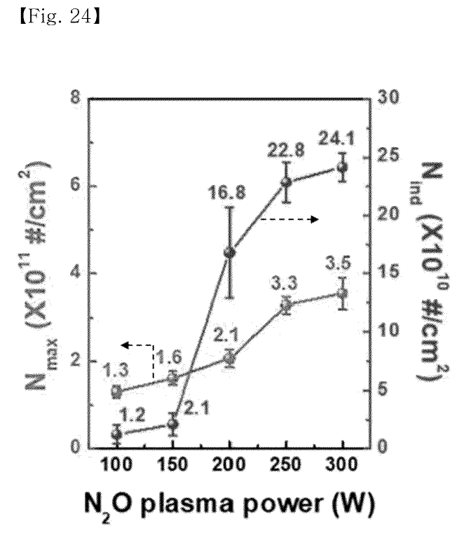

FIG. 21 is a view for describing the results of measuring transfer properties of semiconductor devices according to Experimental Examples 2-1 to 2-5 of the present invention, FIG. 22 is a view for describing the results of measuring threshold voltage and mobility of semiconductor devices according to Experimental Examples 2-1 to 2-5 of the present invention, FIG. 23 is a view for describing the results of measuring subthreshold swing and hysteresis of semiconductor devices according to Experimental Examples 2-1 to 2-5 of the present invention, and FIG. 24 is a view for describing the calculated Nₘₐₓ and N_{ind} values of semiconductor devices according to Experimental Examples 2-1 to 2-5 of the present invention.

Referring to FIG. 21, it can be confirmed that as the plasma power for forming the gate insulating layer increases, the interface properties between the active layer and the gate insulating layer deteriorate.

Referring to FIG. 22, it can be confirmed that as the plasma power for forming the gate insulating layer increases from 100 W to 300 W, a threshold voltage (V_{TH}) increases from −1.1 V to 3.7 V, and a field effect mobility (μ_{FE}) decreases from 33.4 to 24.3 cm²/V-s.

Referring to FIG. 23, it can be confirmed that as the plasma power increases from 100 W to 300 W, a subthreshold swing (SS) value increases from 90 mV/decade to 130 mV/decade, and a hysteresis increases from 0.0 V to 0.6 V.

Referring to FIG. 24, it may show the result of calculating an equivalent maximum trap density (Nₘₐₓ) and a threshold voltage (V_{TH}) induced trap density (N_{ind}) near an interface between the active layer and the gate insulating layer in order to more deeply understand the subthreshold swing and the hysteresis. Nₘₐₓ is calculated through <Equation 1> below, and N_{ind} is calculated through <Equation 2> below.

$${N}_{max} = ( \frac{S . S log ( e )}{kT / q} - 1 ) \frac{{C}_{i}}{q} \qquad < Equation 1 >$$

(k: Boltzmann constant, T: Absolute temperature, q: Electronic charge, Cᵢ: Capacitance of gate insulating layer)

$${N}_{ind} = \frac{{C}_{i} {V}_{hys}}{q} \qquad < Equation 2 >$$

As can be seen in FIG. 24, it can be confirmed that as the plasma power increases from 100 W to 300 W, the calculated Nₘₐₓ and N_{ind} values increase from 1.3×10¹¹ to 3.5×10¹¹/cm² and from 1.2×10¹⁰ to 2.4×10¹¹/cm², respectively. In particular, it can be confirmed that as the plasma power increases from 150 W to 200 W, the N_{ind} value significantly increases from 2.1×10¹⁰/cm² to 1.6×10¹¹/cm². In other words, it can be seen that as the plasma power increases from 150 W to 200 W, a charge trap by the gate insulating layer significantly increases. Accordingly, it can be seen that when the nitrogen-doped SiO₂ material layer is used as a single gate insulating layer, N₂O plasma power for forming the gate insulating layer needs to be controlled to be less than 200 W.

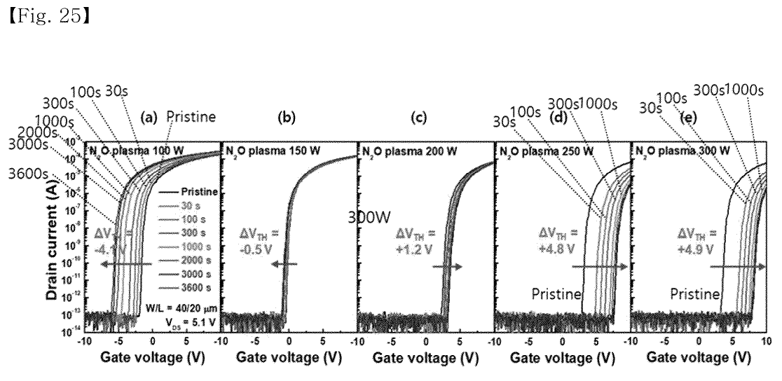

FIG. 25 is a view for describing the results of PBTS test of semiconductor devices according to Experimental Examples 2-1 to 2-5 of the present invention.

Referring to (a) of FIG. 25, it may show the result of PBTS test of the semiconductor device according to Experimental Example 2-1. Referring to (b) of FIG. 25, it may show the result of PBTS test of the semiconductor device according to Experimental Example 2-2. Referring to (c) of FIG. 25, it may show the result of PBTS test of the semiconductor device according to Experimental Example 2-3. Referring to (d) of FIG. 25, it may show the result of PBTS test of the semiconductor device according to Experimental Example 2-4. And, referring to (e) of FIG. 25, it may show the result of PBTS test of the semiconductor device according to Experimental Example 2-5.

The PBTS (positive bias temperature stress) test may be a useful indicator for analyzing an interface defect density because an electron trapping phenomenon at an interface between the active layer and the gate insulating layer occurs better than the bulk of the active layer or gate insulating layer. (a) to (e) of FIG. 25 may show the PBTS results when 2 MV/cm gate bias is applied for 3600 seconds at 60E. It can be confirmed that as the plasma power changes to 100, 150, 200, 250, and 300 W, a V_{TH} shift value shows a U-shaped tendency that change to −4.1, −0.5, 1.2, 4.8, and 4.9 V, respectively.

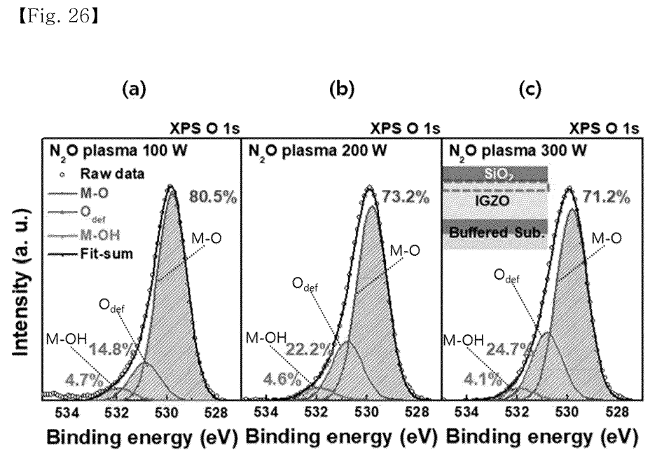

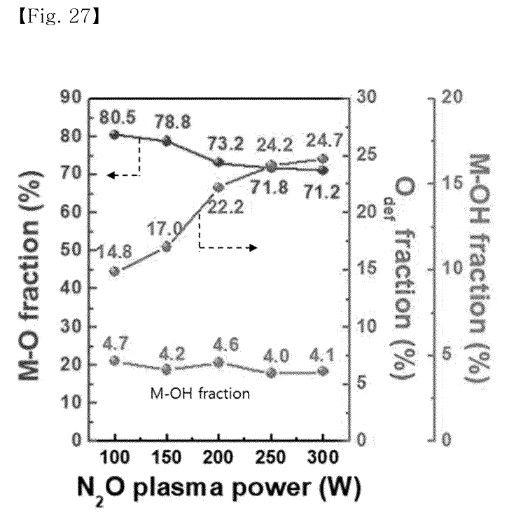

FIGS. 26 and 27 are views for describing the results of XPS analysis of active layers of semiconductor devices according to Experimental Examples 2-1 to 2-5 of the present invention.

Referring to (a) of FIG. 26, it may show a deconvoluted XPS O 1s spectrum at the active layer of the semiconductor device according to above Experimental Example 2-1. Referring to (b) of FIG. 26, it may show a deconvoluted XPS O 1s spectrum at the active layer of the semiconductor device according to above Experimental Example 2-3. Referring to (c) of FIG. 26, it may show a deconvoluted XPS O 1s spectrum at the active layer of the semiconductor device according to above Experimental Example 2-5. And, referring to FIG. 27, it may show a trend according to an XPS O 1s peak analysis.

As can be seen in FIGS. 26 and 27, it can be confirmed that as the plasma power increases from 100 W to 300 W, an M-O ratio decreases from 80.5% to 71.2%, and an O_{def} (oxygen deficient) ratio increases from 14.8% to 24.7%.

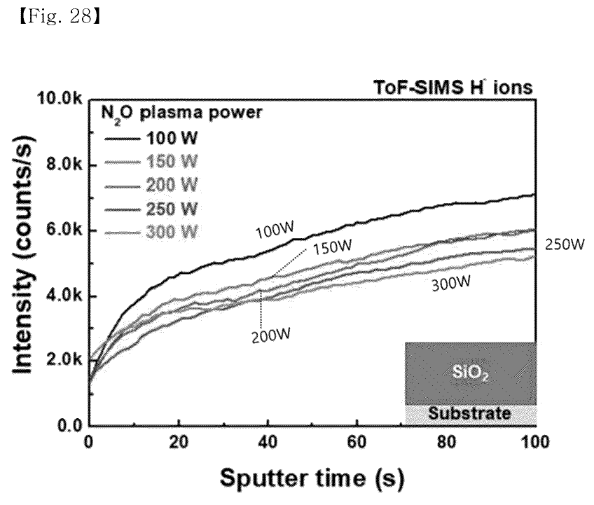

FIG. 28 is a view for describing the results of hydrogen content analysis in the bulk of a gate insulating layer of semiconductor devices according to Experimental Examples 2-1 to 2-5 of the present invention.

Referring to FIG. 28, it may show a ToF-SIMS H⁻ signal of the gate insulating layer (nitrogen-doped SiO₂ material layer) deposited when the plasma power is 100 W to 300 W. As can be seen in FIG. 28, it can be confirmed that the H⁻ signal gradually decreases as the plasma power increases.

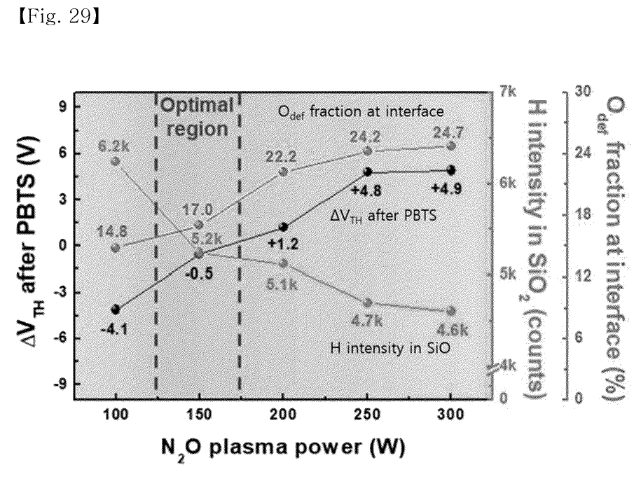

FIG. 29 is a view for describing a change in properties shown after PBTS test of semiconductor devices according to Experimental Examples 2-1 to 2-5 of the present invention.

Referring to FIG. 29, it may show a change in ΔV_{TH} of each semiconductor device, a change in H intensity of the gate insulating layer, and a change in an O_{def} (oxygen deficiency) ratio of the active layer after PBTS. As can be seen in FIG. 29, it can be confirmed that as the plasma power increases, the ΔV_{TH} and O_{def} ratios increase, while the H intensity decreases.

### Experimental Example 3: Comparison of Hydrogen Permeability According to Plasma Power

The semiconductor devices according to Experimental Examples 2-1 to 2-5 as described above were prepared, each of which was heat-treated in a hydrogen (H₂) atmosphere at a temperature of 300° C. to prepare the semiconductor devices according to Experimental Examples 3-1 to 3-5, and the material layers according to Experimental Examples 1-1 to 1-5 as described above were prepared and manufactured on a PI substrate to a thickness of 50 nm to prepare the material layers according to Experimental Examples 3-1 to 3-5.

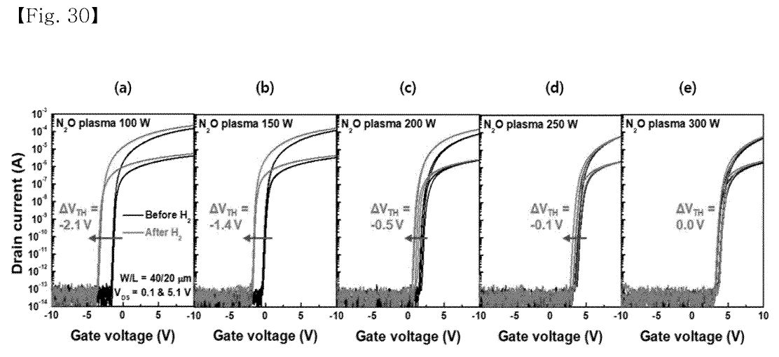

FIG. 30 is a view for describing the results of measuring transfer properties of semiconductor devices according to Experimental Examples 3-1 to 3-5 of the present invention.

Referring to FIG. 30, it can be confirmed that as the plasma power increases from 100 W to 300 W, the negative V_{TH} shift after the hydrogen (H₂) heat treatment decreases from −2.1 V to 0.0 V.

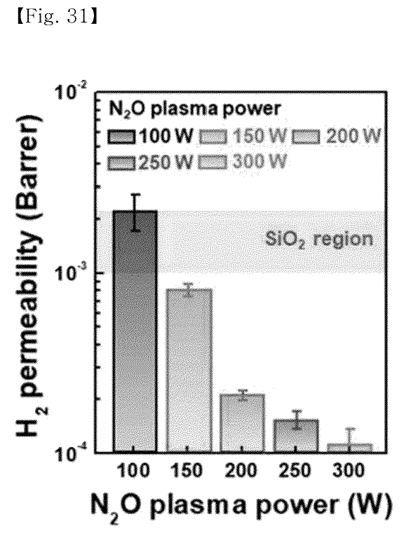

FIG. 31 is a view for describing the results of measuring hydrogen permeability of material layers according to Experimental Examples 3-1 to 3-5 of the present invention.

Referring to FIG. 31, it can be confirmed that as the plasma power increases from 100 W to 300 W, the hydrogen (H₂) permeability decreases from 2.2×10⁻³ Barrer to 1.1×10⁻⁴ Barrer.

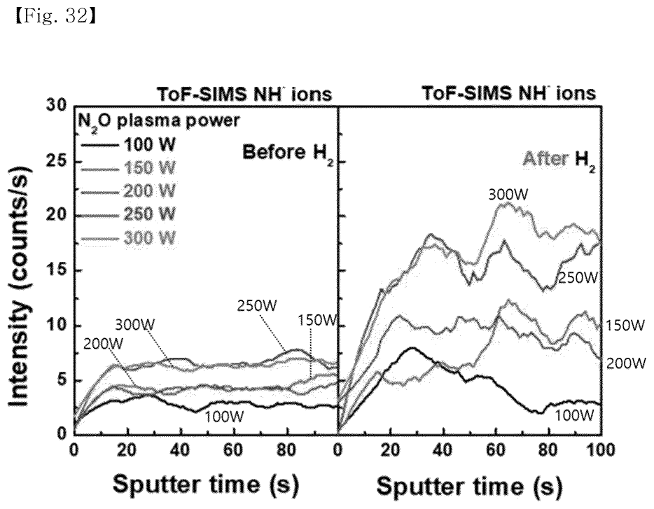

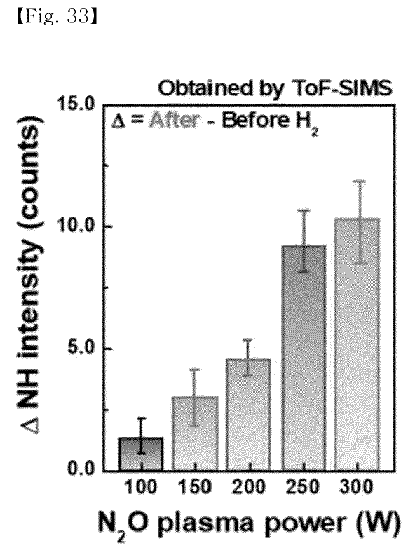

FIGS. 32 and 33 are views for describing the results of Tof-SIMS analysis of material layers according to Experimental Examples 3-1 to 3-5 of the present invention.

Referring to FIG. 32, it may show the results of ToF-SIMS NH⁻ analysis for the material layers according to above Experimental Examples 3-1 to 3-5 before heat treatment (Before H₂) in a hydrogen atmosphere and the material layers according to above Experimental Examples 3-1 to 3-5 after heat treatment (After H₂) in a hydrogen atmosphere, respectively.

As can be seen in FIG. 32, it can be confirmed that the material layers according to Experimental Examples 3-1 to 3-5 before the hydrogen heat treatment show a gradual increase in N—H bond as the plasma power increases. In addition, it can be confirmed that the N—H bond of the material layers according to Experimental Examples 3-1 to 3-5 is clearly increased after the hydrogen heat treatment.

Referring to FIG. 33, it may show a difference between NH intensity measured in a state before heat treatment in a hydrogen atmosphere and NH intensity measured in a state after heat treatment in a hydrogen atmosphere for each of the material layers according to above Experimental Examples 3-1 to 3-5.

As can be seen in FIG. 33, it can be confirmed that as the plasma power increases, the difference in NH intensity increases. In other words, it can be confirmed that the content of hydrogen in the material layer increases as the plasma power increases.

As can be seen in Experimental Example 3, it can be found that when a nitrogen-doped SiO₂ material layer is formed by plasma enhanced atomic layer deposition using N₂O plasma, the hydrogen permeability of the nitrogen-doped SiO₂ material layer decreases as the power of N₂O plasma increases. In other words, it can be seen that the nitrogen-doped SiO₂ material layer manufactured with a strong plasma power has a low hydrogen permeability, whereas the nitrogen-doped SiO₂ material layer manufactured with a weak plasma power has a high hydrogen permeability. Thus, it can be seen that a plasma power of more than 100 W needs to be used at least to prevent hydrogen from permeating into the active layer using the nitrogen-doped SiO₂ material layer as the gate insulating layer.

As a result, as seen in Experimental Examples 1 to 3, it can be found that when the nitrogen-doped SiO₂ material layer formed by plasma enhanced atomic layer deposition using N₂O plasma is used as a gate insulating layer of a top gate bottom contact (TG-BC) structure TFT, the power of N₂O plasma used to form the gate insulating layer needs to be controlled to be more than 100 W and less than 200 W in order to prevent electrical properties from deteriorating and prevent hydrogen from permeating into the active layer.

### Experimental Example 4: Comparison of Single Structure and Stacked Structure of Nitrogen-Doped SiO₂ Gate Insulating Layer

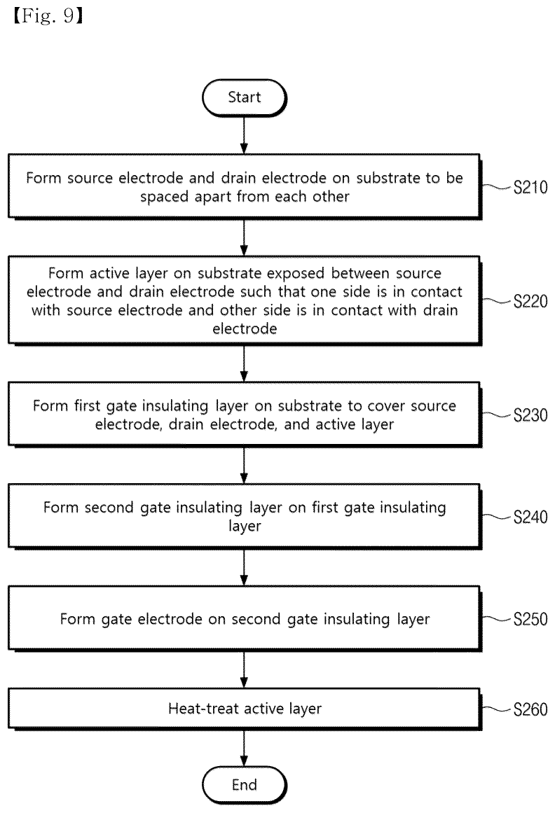

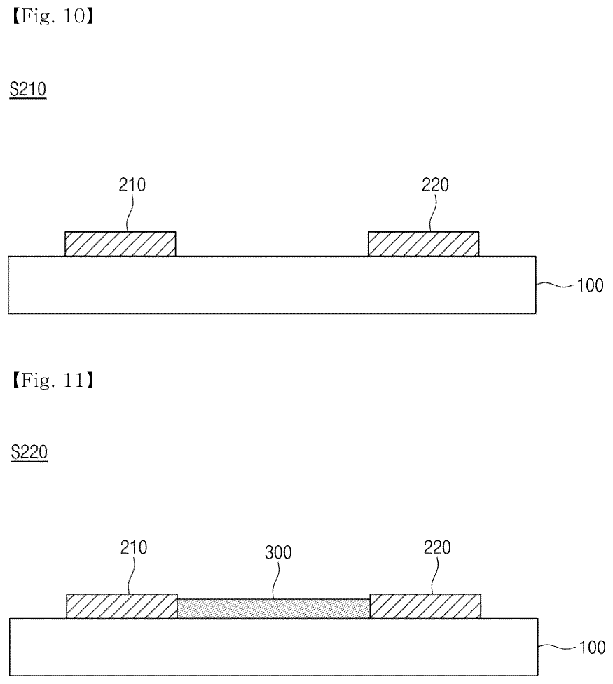

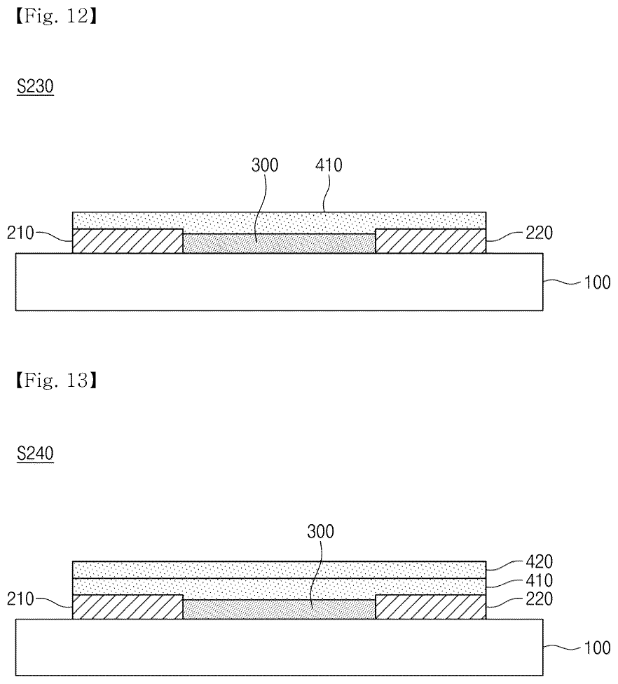

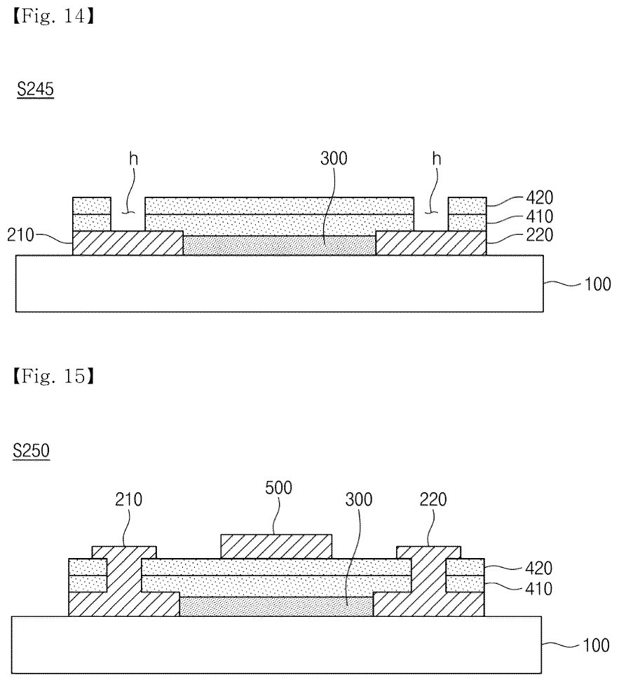

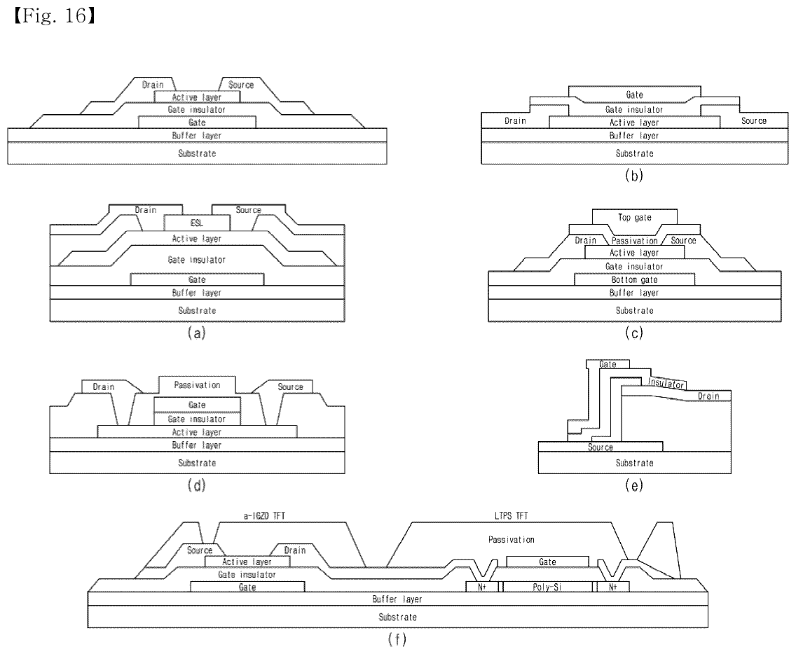

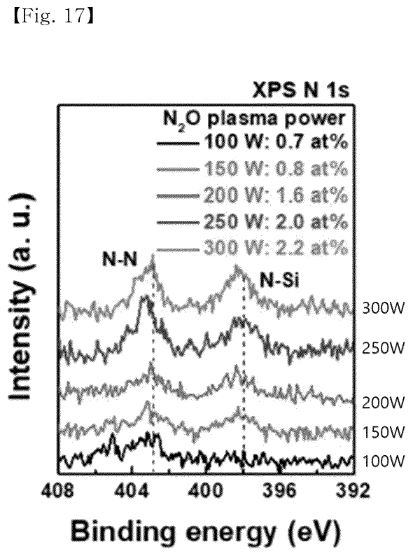

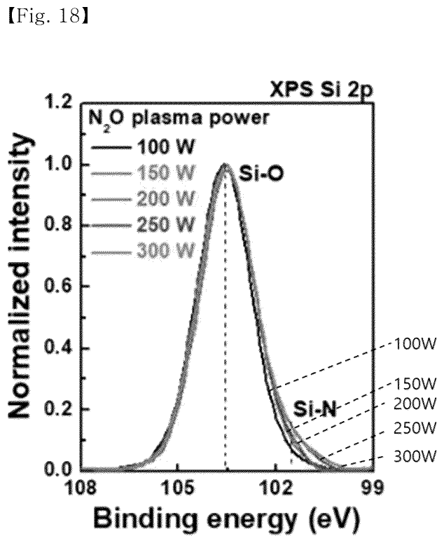

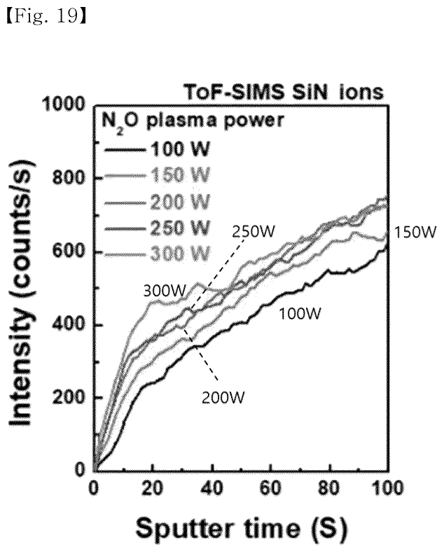

The semiconductor device according to Experimental Example 2-2 as described above was prepared as the semiconductor device (Ex 4-1) according to Experimental Example 4-1. In addition, a TFT device having the structure shown in FIG. 15 was prepared as a semiconductor device (Ex 4-2) according to Experimental Example 4-2 by the method described with reference to FIGS. 9 to 15. More specifically, the semiconductor device according to Experimental Example 4-2 was manufactured to be the same as the semiconductor device according to Experimental Example 4-1, except that a second gate insulating layer was stacked on a first gate insulating layer instead of a single gate insulating layer. In addition, the first gate insulating layer was manufactured using N₂O plasma of 150 W, and the second gate insulating layer was manufactured using N₂O plasma of 300 W.

TABLE 3

| Classification | Gate insulating layer structure | Plasma power |
|---|---|---|
| Ex 4-1 | Nitrogen-doped SiO₂ single layer | 150 W |
| Ex 4-2 | Lower nitrogen-doped SiO₂/ | 150 W/300 W |
| | Upper nitrogen-doped SiO₂ stacked | |

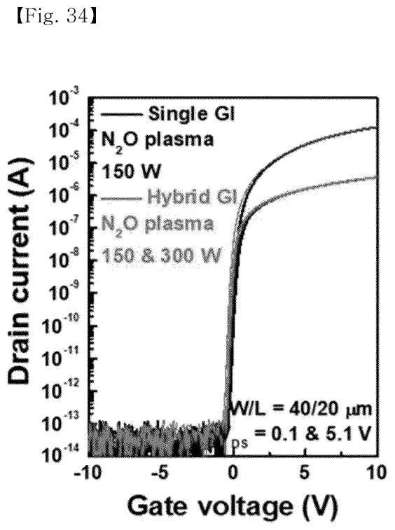

FIG. 34 is a view for describing the results of measuring transfer properties of semiconductor devices according to Experimental Examples 4-1 and 4-2 of the present invention.

Referring to FIG. 34, it may show the transfer properties measured for each of the semiconductor device (single Gi) according to above Experimental Example 4-1 and the semiconductor device (hybrid GI) according to above Experimental Example 4-2. As can be seen in FIG. 34, it can be confirmed that there is no significant difference in transfer properties between the semiconductor device according to above Experimental Example 4-1 and the semiconductor device according to above Experimental Example 4-2.

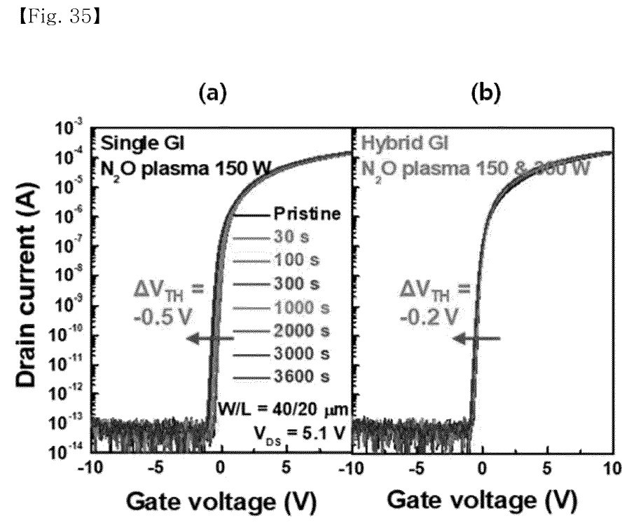

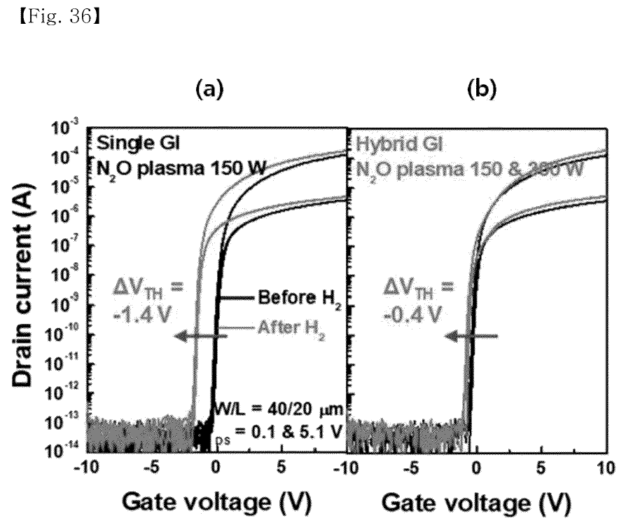

FIGS. 35 and 36 are views for describing the results of PBTS test of semiconductor devices according to Experimental Examples 4-1 and 4-2 of the present invention.

Referring to (a) of FIG. 35, it may show the result of PBTS test of the semiconductor device (single GI) according to above Experimental Example 4-1. Referring to (b) of FIG. 35, it may show the result of PBTS test of the semiconductor device (hybrid GI) according to above Experimental Example 4-2.

As can be seen in (a) and (b) of FIG. 35, it can be confirmed that the PBTS stability of the semiconductor device (Ex 4-2) having the hybrid GI is improved by 60% and the V_{T} shift is changed from −0.5 V to −0.2 V compared to the semiconductor device (Ex 4-1) having the single GI.

Referring to (a) of FIG. 36, it may show the result of PBTS test for each of states before (before H₂) and after (after H₂) the semiconductor device (single GI) according to above Experimental Example 4-1 is heat-treated at 300° C. in a hydrogen atmosphere. Referring to (b) of FIG. 36, it may show the result of PBTS test for each of states before (before H₂) and after (after H₂) the semiconductor device (hybrid GI) according to above Experimental Example 4-2 is heat-treated at 300° C. in a hydrogen atmosphere.

As can be seen in (a) and (b) of FIG. 36, it can be confirmed that the semiconductor device (Ex 4-2) having the hybrid GI after the hydrogen heat treatment process shows an improvement of 71% in a degree of the negative V_{TH} shift, and the V_{TH} shift changes from −1.4 V to −0.4 V.

As a result, it can be seen that the semiconductor device (Ex 4-2) having the hybrid GI has higher reliability and higher stability than the semiconductor device (Ex 4-1) having the single GI.

### Experimental Example 5: Comparison of Property Difference According to Thickness of Gate Insulating Layer in Stacked Structure of Gate Insulating Layer

The semiconductor device according to above Experimental Example 4-2 as described above was prepared, in which a semiconductor device manufactured to have a lower gate insulating layer with a thickness of 10 nm and an upper gate insulating layer with a thickness of 40 nm was prepared as the semiconductor device (Ex 5-1) according to Experimental Example 5-1, a semiconductor device manufactured to have a lower gate insulating layer with a thickness of 30 nm and an upper gate insulating layer with a thickness of 20 nm was prepared as the semiconductor device (Ex 5-2) according to Experimental Example 5-2, and a semiconductor device manufactured to have a lower gate insulating layer with a thickness of 40 nm and an upper gate insulating layer with a thickness of 10 nm was prepared as the semiconductor device (Ex 5-3) according to Experimental Example 5-3.

TABLE 4

| | Thickness of lower | Thickness of upper |
|---|---|---|
| | gate insulating layer | gate insulating layer |
| | and plasma power | and plasma power |
| Classification | (Nitrogen-doped SiO₂) | (Nitrogen-doped SiO₂) |
| Ex 5-1 | 10 nm/150 W | 40 nm/300 W |
| Ex 5-2 | 30 nm/150 W | 20 nm/300 W |
| Ex 5-3 | 40 nm/150 W | 10 nm/300 W |

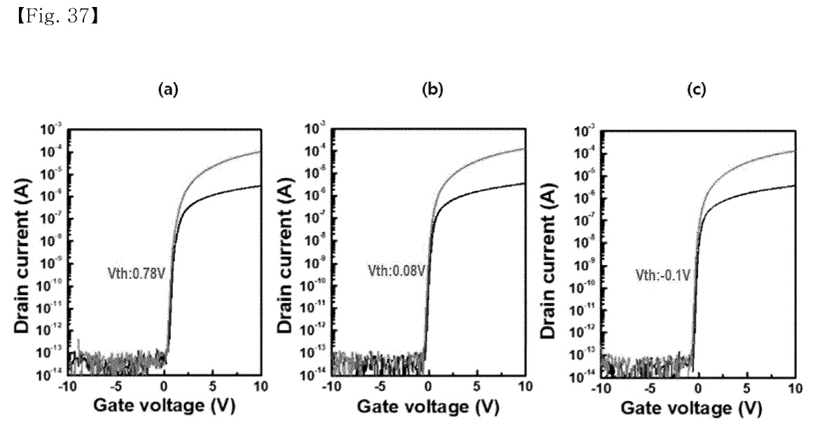

FIG. 37 is a view for describing the results of measuring transfer properties of semiconductor devices according to Experimental Examples 5-1 to 5-3 of the present invention.

Referring to (a) of FIG. 37, it may show the result of measuring transfer properties of the semiconductor device according to above Experimental Example 5-1. Referring to (b) of FIG. 37, it may show the result of measuring transfer properties of the semiconductor device according to above Experimental Example 5-2. And, referring to (c) of FIG. 37, it may show the result of measuring transfer properties of the semiconductor device according to above Experimental Example 5-3.

As can be seen in (a) to (c) of FIG. 37, it can be confirmed that as the thickness of the lower gate insulating layer increases and the thickness of the upper gate insulating layer decreases (Ex 5-1->Ex 5-2->Ex 5-3), the Vₜₕ value decreases (0.78 V->0.08 V->0.1 V).

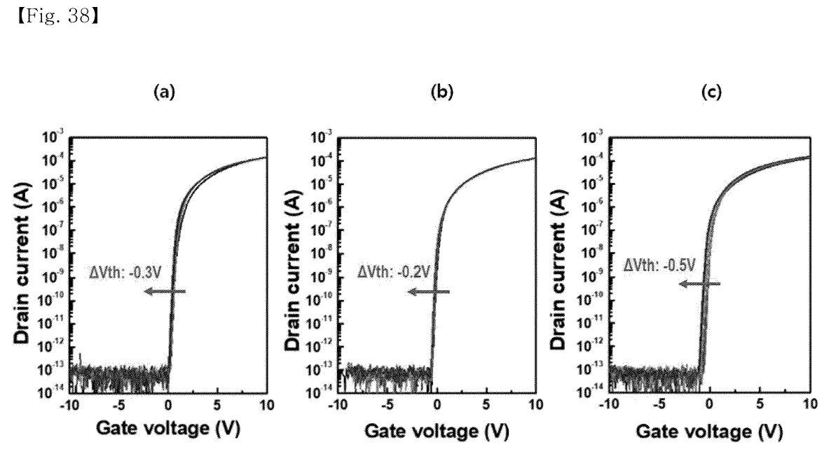

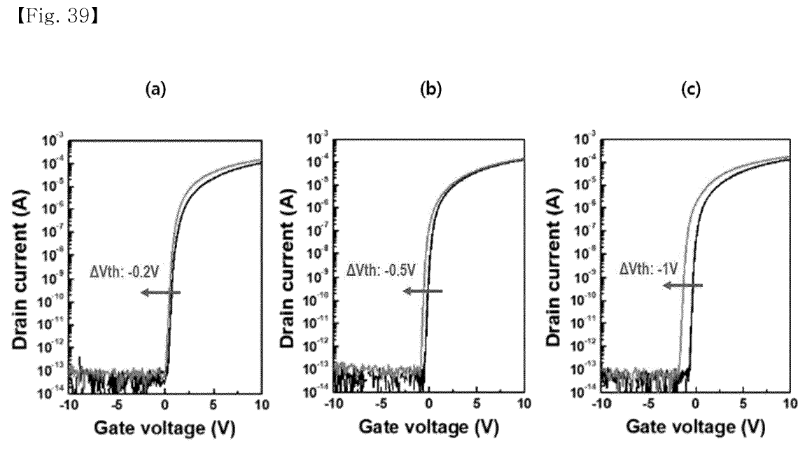

FIGS. 38 and 39 are views for describing the results of PBTS test of semiconductor devices according to Experimental Examples 5-1 to 5-3 of the present invention.

Referring to (a) of FIG. 38, it may show the result of PBTS test of the semiconductor device according to above Experimental Example 5-1. Referring to (b) of FIG. 38, it may show the result of PBTS test of the semiconductor device according to above Experimental Example 5-2. And, referring to (c) of FIG. 38, it may show the result of measuring PBTS test of the semiconductor device according to above Experimental Example 5-3.

As can be seen in (a) to (c) of FIG. 38, it can be confirmed that as the thickness of the lower gate insulating layer increases and the thickness of the upper gate insulating layer decreases (Ex 5-1->Ex 5-2->Ex 5-3), the ΔVₜₕ value changes (−0.3 V->−0.2 V->0.5 V).

Referring to (a) of FIG. 39, it may show the result of PBTS test of the semiconductor device according to above Experimental Example 5-1, subjected to hydrogen heat treatment (H₂ annealing). Referring to (b) of FIG. 39, it may show the result of PBTS test of the semiconductor device according to above Experimental Example 5-2, subjected to hydrogen heat treatment (H₂ annealing). And, referring to (c) of FIG. 39, it may show the result of measuring PBTS test of the semiconductor device according to above Experimental Example 5-3, subjected to hydrogen heat treatment (H₂ annealing).

As can be seen in (a) to (c) of FIG. 39, it can be confirmed that as the thickness of the lower gate insulating layer increases and the thickness of the upper gate insulating layer decreases (Ex 5-1->Ex 5-2->Ex 5-3), the ΔVₜₕ value changes (−0.2 V->−0.5 V->−1 V).

Although the present invention has been described in detail using preferred embodiments, the scope of the present invention is not limited to specific embodiments and should be interpreted by the appended claims. In addition, it should be understood by those skilled in the art that many modifications and variations are possible without departing from the scope of the present invention.

### LIST OF REFERENCE NUMBERS

100: Substrate
210, 220: Source electrode, Drain electrode
300: Active layer
400, 410, 420: Gate insulating layer, First gate insulating layer, Second insulating layer
500: Gate electrode

What is claimed is:

1. A method for manufacturing a semiconductor device, the method comprising:
forming a source electrode and a drain electrode on a substrate to be spaced apart from each other;
forming an active layer on the substrate exposed between the source electrode and the drain electrode such that one side is in contact with the source electrode and an other side is in contact with the drain electrode;
forming a gate insulating layer on the substrate to cover the source electrode, the drain electrode, and the active layer; and
forming a gate electrode on the gate insulating layer, in which
the gate insulating layer is formed by plasma enhanced atomic layer deposition (PEALD) using a precursor including silicon (Si) and a reactant including nitrogen (N) and oxygen (O).

2. The method of claim 1, wherein the reactant includes a nitrous oxide plasma (N₂O plasma), and
a plasma power of the reactant is controlled to be more than 100 W and less than 200 W.

3. The method of claim 1, wherein the gate insulating layer prevents hydrogen from permeating into the active layer.

4. The method of claim 3, wherein as the gate insulating layer is formed by the plasma enhanced atomic layer deposition (PECVD), a dangling bond is formed in the gate insulating layer, and
as the dangling bond in the gate insulating layer is bonded to hydrogen, the permeation of hydrogen into the active layer is prevented.

5. The method of claim 1, wherein the gate insulating layer includes a nitrogen-doped silicon oxide (SiO₂).

6. The method of claim 1, wherein the forming of the gate insulating layer includes:
providing the precursor on the substrate;
a primary purge step of removing unreacted impurities on the substrate provided with the precursor;
providing the reactant on the substrate; and
a secondary purge step of removing the unreacted impurities on the substrate provided with the reactant.

7. The method of claim 1, further comprising:
heat-treating the active layer after the forming of the gate electrode.

8. A method for manufacturing a semiconductor device, the method comprising:
forming a source electrode and a drain electrode on a substrate to be spaced apart from each other;
forming an active layer on the substrate exposed between the source electrode and the drain electrode such that one side is in contact with the source electrode and an other side is in contact with the drain electrode;
forming a first gate insulating layer on the substrate to cover the source electrode, the drain electrode, and the active layer;
forming a second gate insulating layer on the first gate insulating layer; and
forming a gate electrode on the second gate insulating layer, in which
the first gate insulating layer and the second gate insulating layer are all formed by plasma enhanced atomic layer deposition (PEALD) using a precursor including silicon (Si) and a reactant including nitrogen (N) and oxygen (O).

9. The method of claim 8, wherein the reactant includes nitrous oxide plasma (N₂O plasma), in which
the reactant used in a process of forming the first gate insulating layer is controlled to have a relatively low plasma power, and
the reactant used in a process of forming the second gate insulating layer is controlled to have a relatively high plasma power.

10. The method of claim 9, wherein the reactant used in the process of forming the first gate insulating layer is controlled to have a plasma power of 150 W, and
the reactant used in the process of forming the second gate insulating layer is controlled to have a plasma power of 300 W.

11. A semiconductor device comprising:
a source electrode disposed on a substrate;
a drain electrode disposed on the substrate to be spaced apart from the source electrode;
an active layer disposed on the substrate exposed between the source electrode and the drain electrode such that one side is in contact with the source electrode and an other side is in contact with the drain electrode;
a first gate insulating layer covering the source electrode, the drain electrode, and the active layer and including a nitrogen-doped silicon oxide;
a second gate insulating layer disposed on the first gate insulating layer and including a nitrogen-doped silicon oxide; and
a gate electrode disposed on the second gate insulating layer, in which
a content of nitrogen in the second gate insulating layer is greater than a content of nitrogen in the first gate insulating layer.

12. The semiconductor device of claim 11, wherein the content of nitrogen in the first gate insulating layer is less than 1 at %, and
the content of nitrogen in the second gate insulating layer is greater than 2 at %.

13. The semiconductor device of claim 11, wherein a hydrogen permeability of the second gate insulating layer is lower than a hydrogen permeability of the first gate insulating layer.

14. The semiconductor device of claim 11, wherein the active layer includes an indium gallium zinc oxide (IGZO).
